(19) United States
(12) Patent Application Publication
(10) Pub. No.: US 2019/0157858 A1
(43) Pub. Date: May 23, 2019

(54) PROXIMITY SENSING TEMPERATURE CONTROLLED POWER ADAPTER AND METHOD OF OPERATION

(71) Applicant: Xentris Wireless LLC, Addison, IL (US)

(72) Inventors: Vivek Patel, Elk Grove Village, IL (US); Terrell Morrow, Elgin, IL (US)

(21) Appl. No.: 15/818,156

(22) Filed: Nov. 20, 2017

(51) Int. Cl. H02H 5/04; H03K 17/945; H05K 7/20

(52) U.S. Cl. CPC H02H 5/047; G01K 13/00; H05K 7/20909; H03K 17/945

(57) ABSTRACT

A power adapter and method of use wherein a power adapter provided with a power supply portion and human detection and cooling circuitry may be cooled and/or disabled upon detection of a human proximate the power adapter. In use, a voltage regulator integrated circuit of the power adapter is disabled if an overload temperature is sensed. Alternatively, if a human presence is sensed proximate the power adapter, the voltage regulator integrated circuit is also disabled and a cooling fan is energized.

### BACKGROUND

### Field of the Invention

This invention relates to Alternating Current (AC) and Direct Current (DC) Power Adapters, also referred to as power supplies, car and/or wall adapters. More particularly, the invention relates to a Power Adapter with proximity sensing temperature control.

### Description of Related Art

Power Adapters are used to provide DC electrical power for a wide range of power consuming devices, such as cellular telephones and other power consuming devices for ongoing operation of such devices and/or for re-charging batteries of these devices. Many power consuming devices have standardized power requirements, such as the 5 Volt Direct Current (VDC) power available from a Universal Serial Bus (USB) interface, enabling a single Power Adapter to be utilized to power and/or charge different devices and/or multiple devices simultaneously.

Introduction of Power Adapter standards with high power capability, such as USB-C, enable high power quick-charge and/or wireless charging technologies. However, increased current usage may increase the operating temperature of a power adapter.

Therefore, an object of the invention is to provide Power Adapter solutions that overcome deficiencies in the prior art.

### BRIEF DESCRIPTION OF THE DRAWINGS

The accompanying drawings, which are incorporated in and constitute a part of this specification, illustrate embodiments of the invention, where like reference numbers in the drawing figures refer to the same feature or element and may not be described in detail for every drawing figure in which they appear and, together with a general description of the invention given above, and the detailed description of the embodiments given below, serve to explain the principles of the invention.

FIG. 1 is a schematic block diagram of an exemplary Power Adapter with human detection and cooling functionality.

FIG. 2 is a schematic block diagram of an exemplary AC power adapter.

FIG. 3 is a schematic block diagram of an exemplary DC power adapter.

FIG. 4 is a schematic operation flow chart for a Power Adapter with human detection and cooling functionality.

### DETAILED DESCRIPTION

The inventors have recognized that although Power Adapters with high current capability may be configured via materials selection and/or circuit design/layout to safely operate at high operating temperatures for extended periods, these high temperatures may alarm and/or burn users unaccustomed to these operating temperatures.

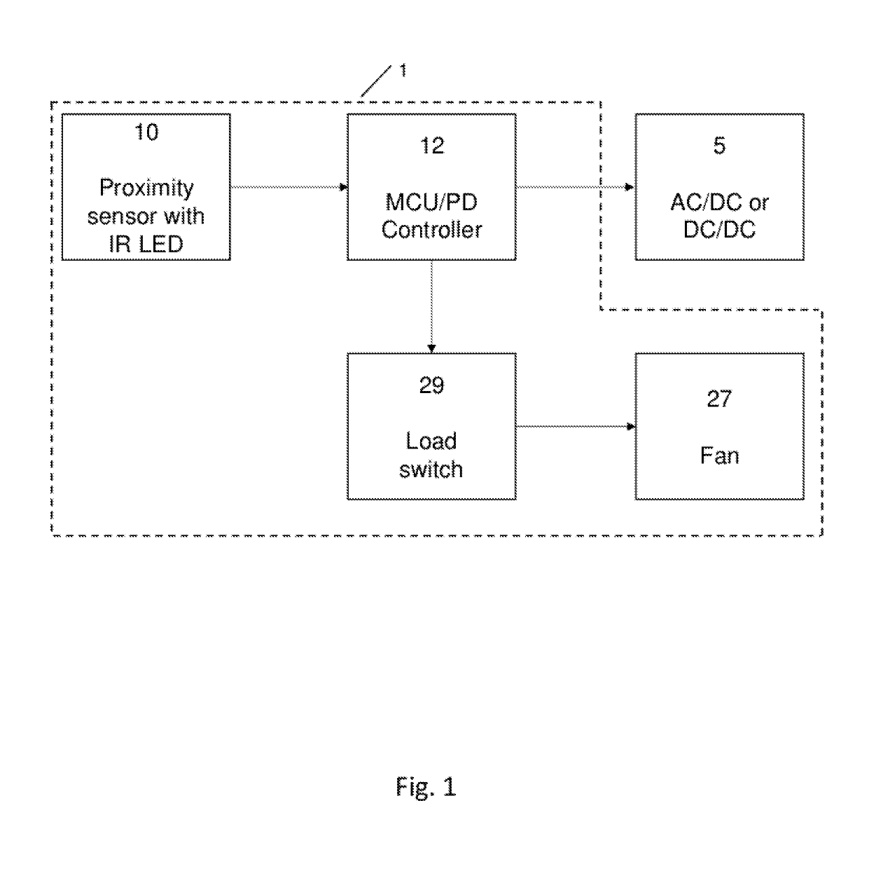

An exemplary block diagram for a power adapter with proximity sensing temperature control is shown in FIG. 1. The power adapter has a conventional AC/DC or DC/DC voltage regulator 5 for control of the conversion of an input voltage to a stable output voltage (VBUS). Failsafe circuitry, including a temperature sensor T, of the voltage regulator integrated circuit 15 monitors the power adapter for out of range temperature and/or current levels, disabling the power adapter if out of range (potentially power adapter damaging) parameters are sensed.

For human proximity detection, a sensor 10 provides an input signal to a Micro-Controller Unit (MCU) 12. The sensor 10 is configured to detect the presence of a human (such as a human hand) proximate the power adapter. When an interrupt signal corresponding to proximity of a human is received from the sensor 10 by the MCU 12, the MCU 12 initiates a cool-down mode.

The cool-down mode may include disabling the VBUS and/or energizing a cooling fan 27 of the power adapter.

The MCU 12 can maintain the cool-down mode until the sensor 10 no longer detects the presence of the human.

The sensor 10 may be provided, for example, as an Infrared (IR) light emitting diode (LED) 14 coupled to a LED driver and proximity sensor 16, or an integrated circuit with IR proximity detection functionality. The proximity sensor 16 will generate the interrupt signal, for example HIGH if it is active low and LOW if it is active high. The interrupt signal could be, for example, either an open drain or push pull type.

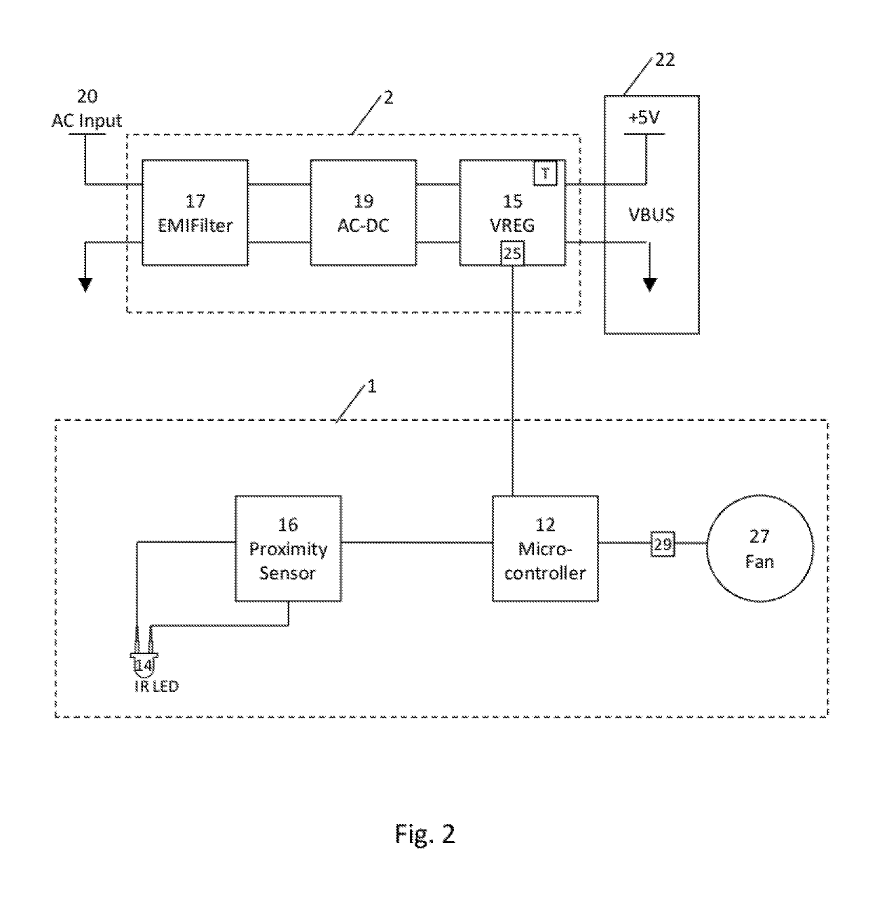

In an exemplary AC Power Adapter embodiment, shown in FIG. 2, the power supply portion 2 of an exemplary AC Power Adapter may include filter 17, rectification/transformation 19 and voltage regulator integrated circuit 15 to transform the standard main AC Input 20, such as 120 or 220 Volt Alternating Current@60 or 50 Hertz to a desired voltage bus (VBUS), such as 5 VDC. The VBUS may be provided as, for example, a USB interface 22.

Human proximity detection and cooling circuitry 1 may be tied to the voltage regulator 15 of the power supply portion 2 via an enable/disable output of the MCU 12 tied to the enable/disable input 25 of the voltage regulator integrated circuit 15. The fan enable output of the MCU 12, such as a GPIO (general purpose input output) of the MCU 12, may be coupled to the fan 27 via a semi-conductor switch 29, for example a metal-oxide semiconductor field-effect transistor (MOSFET).

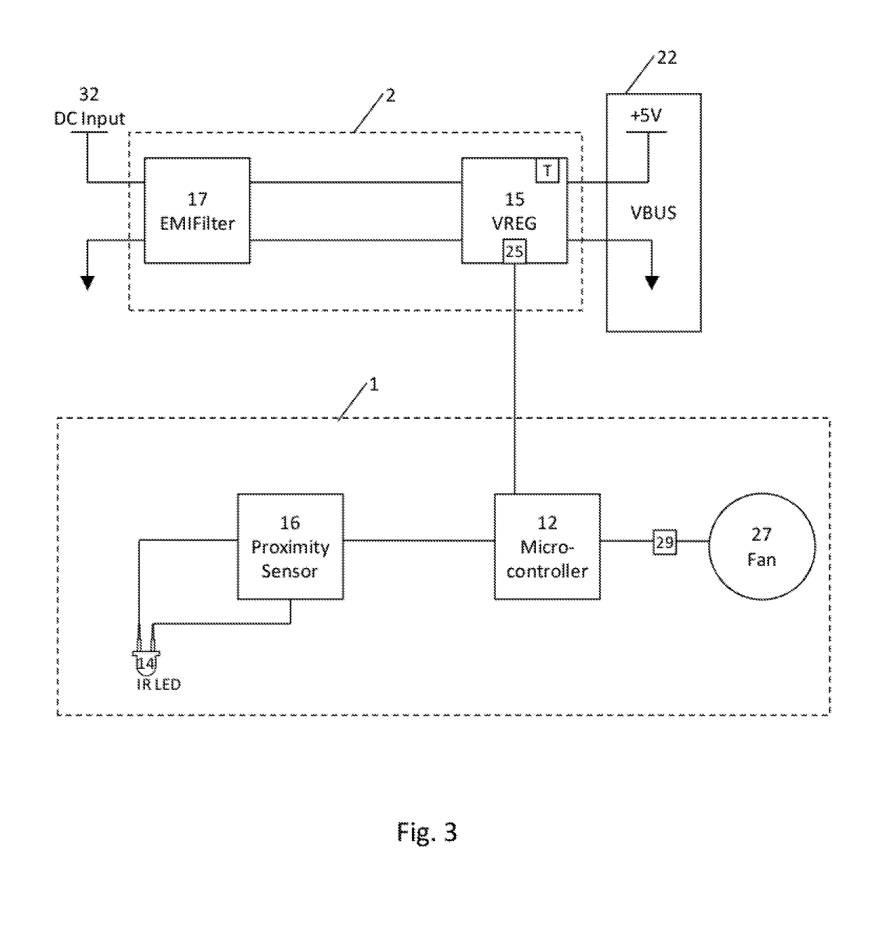

Similarly, FIG. 3 shows an exemplary DC Power Adapter embodiment where the power supply portion 2 receives DC power 32 passed through a filter 17 to the voltage regulator 15. The voltage regulator integrated circuit 15 is again coupled to human detection and cooling circuitry 1 via the enable/disable input 25 to the voltage regulator integrated circuit 15 as previously described.

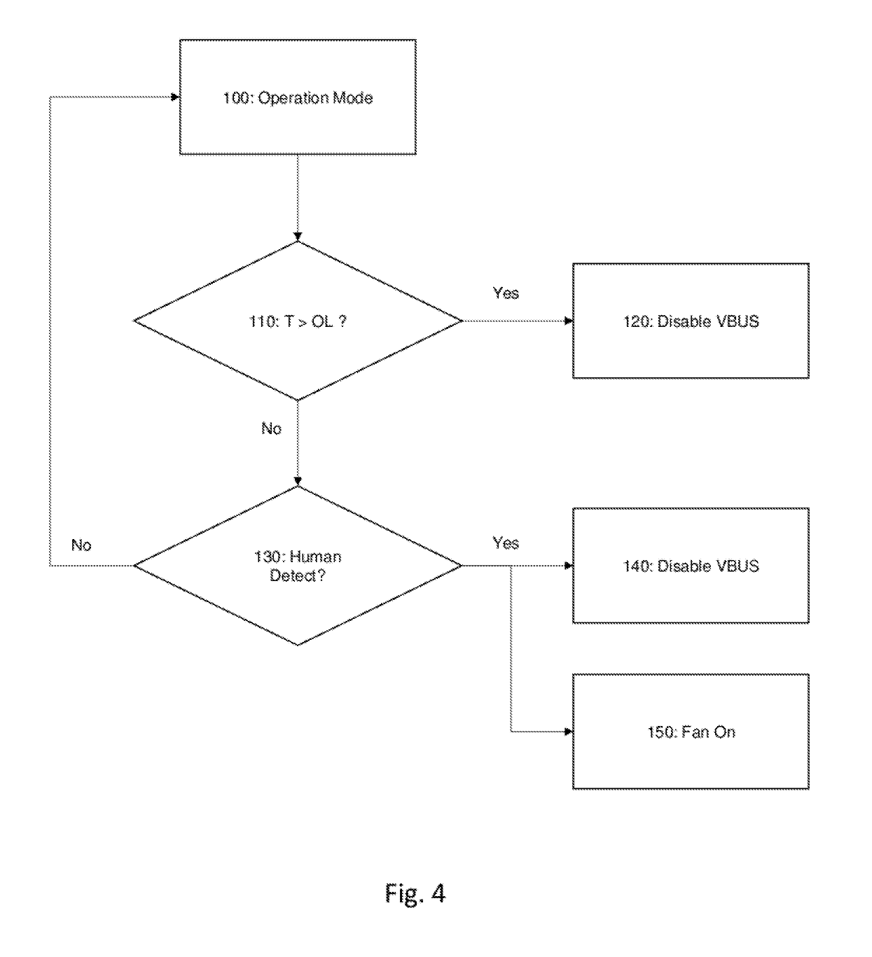

In a method of operation, as shown for example in FIG. 4 and described here below with reference to the elements of the AC Power Adapter circuitry as described with respect to FIG. 2, the Power Adapter has an operation mode 100 wherein the AC power 20 (or DC power 32, in the case of a DC power adapter) is converted to the desired VBUS. As long as the Power Adapter is coupled to input power 20, the Power Adapter remains on, unless:
1) The voltage regulator integrated circuit 15 failsafe circuitry detects an overload temperature (110), voltage or current parameter; or
2) The enable signal from the human proximity detection and cooling circuitry 1 is removed (130). If a human is detected by the human detection and cooling circuitry 1, the voltage regulator 15 enable signal is disabled, which disables the VBUS (140), in addition the fan 27 is energized (150) to expedite cooling. Thereby, the Power Adapter is no longer heated by operation and is quickly cooled by the fan 27 so the user is not harmed or alarmed by the temperature of the Power Adapter when grasped for example to inspect, connect and/or disconnect electronic apparatus such as cellular phone, tablet or laptop for charging/use.

Table of Parts

| | |
|---|---|
| 1 | Human detection and cooling circuitry |
| 2 | Power supply portion |
| 5 | Voltage regulator |
| 10 | Sensor |
| 12 | Micro-controller unit |
| 14 | Infrared light emitting diode |
| 15 | Voltage regulator integrated circuit |
| 16 | Proximity sensor |
| 17 | Filter |
| 19 | Rectification/transformation |
| 20 | AC input |
| 22 | USB interface |
| 25 | Enable/disable input |
| 27 | Fan |
| 29 | Switch |
| 32 | DC power |
| T | Temperature sensor |

Where in the foregoing description reference has been made to materials, ratios, integers or components having known equivalents then such equivalents are herein incorporated as if individually set forth.

While the present invention has been illustrated by the description of the embodiments thereof, and while the embodiments have been described in considerable detail, it is not the intention of the applicant to restrict or in any way limit the scope of the appended claims to such detail. Additional advantages and modifications will readily appear to those skilled in the art. Therefore, the invention in its broader aspects is not limited to the specific details, representative apparatus, methods, and illustrative examples shown and described. Accordingly, departures may be made from such details without departure from the spirit or scope of applicant's general inventive concept. Further, it is to be appreciated that improvements and/or modifications may be made thereto without departing from the scope or spirit of the present invention as defined by the following claims.

We claim:

1. A power adapter, comprising:
a power supply portion coupled to human detection and cooling circuitry via an enable/disable input of a voltage regulator integrated circuit of the power supply portion;
the voltage regulator integrated circuit provided with a temperature sensor; and
the human detection and cooling circuitry provided with a sensor;
the human detection and cooling circuitry configured to disable the voltage regulator and energize a fan of the human detection and cooling circuitry upon detection of a human presence by the sensor.

2. The power adapter of claim 1, wherein the sensor comprises an infrared light emitting diode and a proximity sensor.

3. The power adapter of claim 2, wherein the proximity sensor is coupled to a microcontroller unit configured to receive an interrupt signal from the proximity sensor when the human presence is sensed.

4. The power adapter of claim 3, wherein the fan is energized by a switch controlled by the microcontroller unit.

5. The power adapter of claim 4, wherein the switch is a semiconductor switch.

6. The power adapter of claim 5, wherein the switch is a metal-oxide semiconductor field-effect transistor.

7. The power adapter of claim 1, wherein the power supply portion has an alternating current input.

8. The power adapter of claim 1, wherein the power supply portion has a direct current input.

9. The power adapter of claim 1, wherein the power supply portion has a voltage bus output configured as a USB interface.

10. A method for operation of a power adapter, comprising:
disabling a voltage regulator integrated circuit of the power adapter if an overload temperature is sensed; and
disabling the voltage regulator integrated circuit of the power adapter and energizing a fan if a human presence is sensed by a sensor of the power adapter.

11. The method of claim 10, wherein the overload temperature is sensed by a temperature sensor of the voltage regulator integrated circuit.

12. The method of claim 10, wherein the sensor comprises an infrared light emitting diode and a proximity sensor.

13. The method of claim 12, further including a microcontroller unit;
the disabling of the voltage regulator integrated circuit and the energizing of the fan initiated by the microcontroller unit upon reception of an interrupt signal from the proximity sensor when the human presence is sensed.

14. The method of claim 13, wherein the microcontroller unit enables a switch to energize the fan.

15. The method of claim 14, wherein the switch is a semiconductor switch.

16. The method of claim 10, wherein once the human presence is sensed, the voltage regulator remains disabled and the fan remains energized until the human presence is no longer sensed by the sensor.

17. The method of claim 10, wherein the power adapter receives an alternating current input.

18. The method of claim 10, wherein the power adapter receives a direct current input.

19. The method of claim 10, wherein the power adapter provides a voltage bus output; the voltage bus output configured as a USB interface.
